(19) United States
(12) Patent Application Publication
(10) Pub. No.: US 2026/0163330 A1
(43) Pub. Date: Jun. 11, 2026

(54) OPTICAL ELEMENT AND MANUFACTURING METHOD HAVING A REVERSE MESA RIDGE STRUCTURE

(71) Applicant: PHOVEL CO., LTD., Daejeon (KR)

(72) Inventor: Jeong Soo KIM, Sejong (KR)

(21) Appl. No.: 19/001,142

(22) Filed: Dec. 24, 2024

Related U.S. Application Data
(60) Provisional application No. 63/728,391, filed on Dec. 5, 2024.

(51) Int. Cl. H01S 5/042; H01S 5/024; H01S 5/22; H01S 5/34

(52) U.S. Cl. CPC H01S 5/04256; H01S 5/02453; H01S 5/22; H01S 5/34

(57) ABSTRACT

Provided is an optical element having a reverse mesa ridge structure in which an electric pad is disposed on top of a benzocyclobutene (BCB) material disposed on one side of the reverse mesa ridge, and the semiconductor ridge and the BCB layer may be spaced apart from each other to have a space therebetween.

### BACKGROUND

The present disclosure relates to an optical element having a reverse mesa ridge structure in which a heater is installed on top of the optical element.

### DESCRIPTION OF THE RELATED ART

A semiconductor laser optical element having a reverse mesa ridge structure has been manufactured either in an independent or an integrated form for current optical communications. A semiconductor laser having the reverse mesa ridge structure has been manufactured in the form of a distributed feedback laser diode (DFB-LD) or a distributed Bragg reflector laser diode (DBR-LD), and has been manufactured either independently or integrated with a modulator.

In particular, for the recently-manufactured optical element having a reverse mesa ridge structure, attempts have been made to manufacture an electric pad to be spaced apart from a semiconductor surface to enable its high-speed operation to thus reduce its capacitance and consequently reduce a resistance-capacitance (RC) time of the optical element, thereby achieving the high-speed operation.

In addition, in recent years, a heater has been installed above a semiconductor light source having the reverse mesa ridge structure, and has been used for wavelength tuning or wavelength stabilization purposes. However, insufficient consideration has been given to a specific manufacturing method of the ridge-structured optical element.

FIGS. 1 and 2 are views for explaining an optical element having a reverse mesa ridge structure, in which a conventional heater is mounted.

Referring to FIG. 1, the optical element 100 having a reverse mesa ridge structure may include a substrate 110, a first cladding layer 120, a multi-quantum well (MQW) active layer 130, a spacer layer 140, a benzocyclobutene (BCB) layer 150, a second cladding layer 160, a first electrode 170, an insulating film 180, and a heater 190.

Thermal expansion coefficients of semiconductor materials in the BCB and indium phosphide (InP) may differ. Accordingly, as shown in FIG. 1, when applying the BCB to the reverse mesa structure, during a process of applying the BCB at a low temperature, curing the BCB at a high temperature, and then returning the temperature to room temperature again, the different thermal expansion coefficients of the semiconductor materials in the BCB and the InP series may cause stress in a semiconductor structure having a reverse mesa ridge, which may reduce semiconductor reliability. That is, the BCB may cause the stress to the reverse mesa ridge structure of the InP due to the difference in the thermal expansion coefficients, thus reducing the semiconductor reliability.

Referring to FIG. 2, heat generated from the heater may be transferred through a BCB layer 200. Accordingly, heat generated from the heater may fail to effectively control a temperature of a semiconductor active region in the MQW, resulting in heat loss.

### SUMMARY

An object of the present disclosure is to provide an optical element having a reverse mesa ridge structure in which an electric pad is disposed on top of a benzocyclobutene (BCB) material disposed on one side of the reverse mesa ridge, and the semiconductor ridge and the BCB layer may be spaced apart from each other to have a space therebetween, thereby preventing semiconductor reliability reduced by a stress occurring in a semiconductor structure having the reverse mesa ridge due to a difference in thermal expansion coefficients of semiconductor materials in the BCB and indium phosphide (InP) series.

According to an embodiment of the present disclosure, provided is an optical element having a reverse mesa ridge structure, the element including: a substrate; a second cladding layer disposed near a center of the top of the substrate; a first benzocyclobutene (BCB) layer disposed on a right side of the second cladding layer and spaced apart from the second cladding layer to have a space therebetween; a second BCB layer disposed on a left side of the second cladding layer and spaced apart from the second cladding layer to have a space therebetween; a light source electrode connecting the top of the second cladding layer to the top of the second BCB layer; an insulating film connecting the top of the light source electrode to the top of the first BCB layer; and a heater disposed on top of the insulating film connecting the top of the light source electrode to the top of the first BCB layer.

The element may further include a first cladding layer disposed on top of the substrate.

The element may further include a multi-quantum well (MQW) active layer disposed on top of the first cladding layer.

The element may further include a spacer layer disposed on top of the MQW active layer, wherein the second cladding layer is disposed near a center of the top of the spacer layer.

The second cladding layer may have a lower width smaller than an upper width.

The two heaters may be disposed on one side of a wave guide to be spaced apart from each other, and the light source electrode may be disposed on the other side of the wave guide, opposite to the one side of the wave guide where the two heaters are disposed.

The two heaters may be disposed on two ends of one side of the wave guide to be spaced apart from each other, and the light source electrode may be disposed between the two heaters and on the other side of the wave guide, opposite to the one side of the wave guide where the two heaters are disposed.

According to another embodiment of the present disclosure, provided is a manufacturing method of an optical element having a reverse mesa ridge structure, the method including: disposing a second cladding layer near a center of the top of a substrate; disposing a benzocyclobutene (BCB) layer on each of two sides of the second cladding layer disposed on top of the substrate; disposing a first BCB layer on a right side of the second cladding layer to be spaced apart from the second cladding layer and a second BCB layer on a left side of the second cladding layer to be spaced apart from the second cladding layer by removing portions of the BCB layers disposed on the two sides of the second cladding layer; applying a photoresist (PR) to the removed BCB layer and filling the removed BCB layer with the photoresist (PR); disposing a light source electrode to connect the top of the second cladding layer to the top of the second BCB layer; disposing an insulating film to connect the top of the light source electrode to the top of the first BCB layer; disposing a heater on top of the insulating film connecting the top of the light source electrode to the top of the first BCB layer; and providing an air bridge structure by removing the photoresist (PR) disposed between the second cladding layer and the first BCB layer and between the second cladding layer and the second BCB layer.

The method may further include disposing a first cladding layer on top of the substrate.

The method may further include disposing a multi-quantum well (MQW) active layer on top of the first cladding layer.

The method may further include disposing a spacer layer on top of the MQW active layer, wherein the second cladding layer is disposed near a center of the top of the spacer layer.

The second cladding layer may have a lower width smaller than an upper width.

### BRIEF DESCRIPTION OF THE DRAWINGS

FIGS. 1 and 2 are views for explaining an optical element having a reverse mesa ridge structure, in which a conventional heater is mounted.

FIG. 3 is a view for explaining an optical element having a reverse mesa ridge structure according to an embodiment of the present disclosure.

FIG. 4 is a view showing a cross-section taken along “reference A” in FIG. 3.

FIG. 5 is a view showing a cross-section taken along “reference B” in FIG. 3.

FIG. 6 is a view showing a cross-section taken along “reference C” in FIG. 3.

FIGS. 7 to 12 are views for explaining a manufacturing method of an optical element having a reverse mesa ridge structure according to an embodiment of the present disclosure.

FIG. 13 is a view for explaining an optical element having a reverse mesa ridge structure according to another embodiment of the present disclosure.

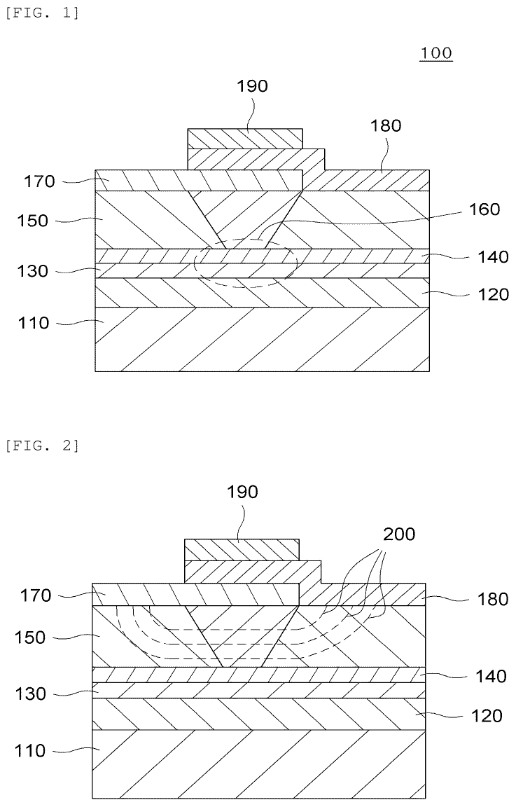

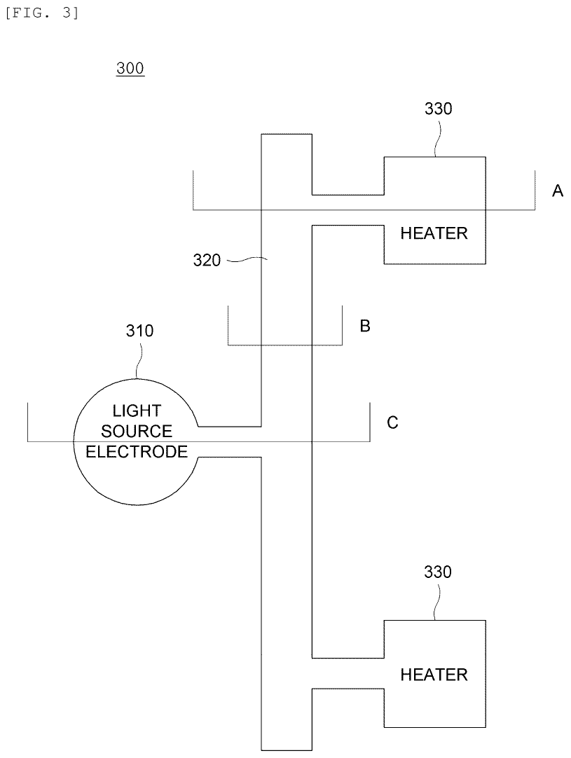

### DETAILED DESCRIPTION

Hereinafter, detailed contents for embodying the present disclosure are described in detail with reference to the accompanying drawings.

FIG. 3 is a view for explaining an optical element having a reverse mesa ridge structure according to an embodiment of the present disclosure.

Referring to FIG. 3, an optical element 300 having a reverse mesa ridge structure may include a light source electrode 310, a wave guide 320, and a heater 330.

The light source electrode 310 may be connected to one side of the wave guide 320. For example, the light source electrode 310 may be connected to the middle of the wave guide 320, and its connection position may be changed in various ways.

For example, the light source electrode 310 may be disposed between the two heaters 330 and on the other side of the wave guide 320, opposite to one side of the wave guide 320 where the two heaters 330 are disposed.

The heater 330 may be connected to each of two ends of the wave guide 320. For example, the two heaters 330 may be provided, one heater being connected to one end of the wave guide 320, and one heater connected to the other end of the wave guide 320.

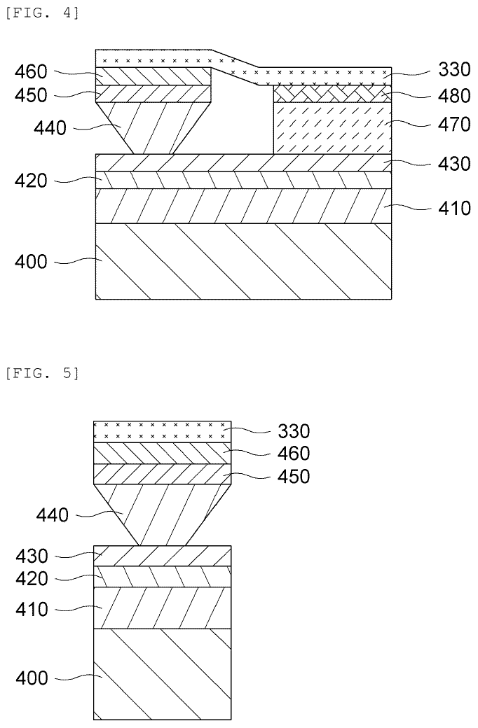

FIG. 4 is a view showing a cross-section taken along “reference A” in FIG. 3.

Referring to FIGS. 3 and 4, based on “reference A”, the optical element 300 having a reverse mesa ridge structure may include a substrate 400, a first cladding layer 410, a multi-quantum well (MQW) active layer 420, a spacer layer 430, a second cladding layer 440, a light source electrode 450, a first insulating film 460, a first BCB layer 470, a second insulating film 480, and the heater 330.

The first cladding layer 410 may be disposed on top of the substrate 400.

The MQW active layer 420 may be disposed on top of the first cladding layer 410.

The spacer layer 430 may be disposed on top of the MQW active layer 420.

The second cladding layer 440 may be disposed on top of one side of the spacer layer 430.

The second cladding layer 440 may have a lower width smaller than an upper width. For example, the second cladding layer 440 may have the reverse mesa structure.

The light source electrode 450 may be disposed on top of the second cladding layer 440 in a light source region. The light source electrode 450 may be a P electrode, and electrons in the electrode may be moved to the spacer layer 430 and the MQW active layer 420 through the second cladding layer 440.

The first insulating film 460 may be disposed between the light source electrode 450 and the heater 330. The first insulating film 460 may insulate the light source electrode 450 and the heater 330 from each other.

The first BCB layer 470 may be disposed on top of the other side of the spacer layer 430, and spaced apart from the second cladding layer 440 to have a space 485 therebetween. Here, the first BCB layer 470 may be replaced with a polyimide layer.

The second insulating film 480 may be disposed on top of the first BCB layer 470.

The heater 330 may connect the top of the first insulating film 460 to the top of the second insulating film 4820.

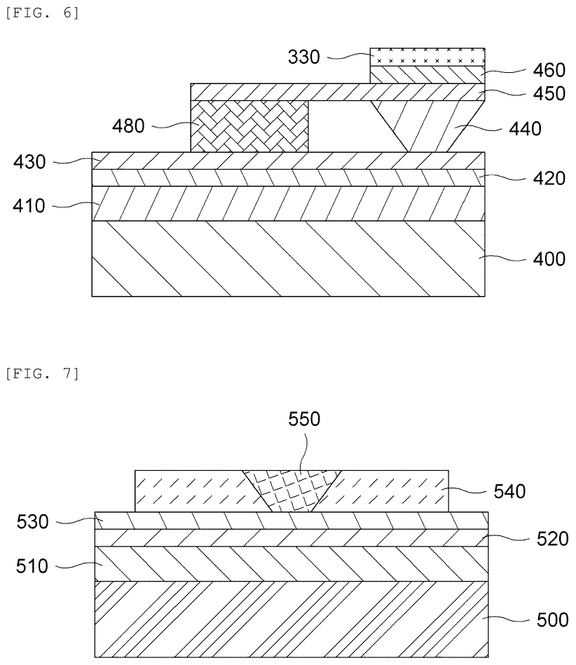

FIG. 5 is a view showing a cross-section taken along “reference B” in FIG. 3.

Referring to FIGS. 3 and 5, based on “reference B”, Referring to FIGS. 3 and 4, based on “reference A” the optical element 300 having a reverse mesa ridge structure may include the substrate 400, the first cladding layer 410, the MQW active layer 420, the spacer layer 430, the second cladding layer 440, the light source electrode 450, the first insulating film 460, and the heater 330.

The first cladding layer 410 may be disposed on top of the substrate 400.

The MQW active layer 420 may be disposed on top of the first cladding layer 410.

The spacer layer 430 may be disposed on top of the MQW active layer 420.

The second cladding layer 440 may be disposed on top of one side of the spacer layer 430.

The second cladding layer 440 may have the lower width smaller than the upper width. For example, the second cladding layer 440 may have the reverse mesa structure.

The light source electrode 450 may be disposed on top of the second cladding layer 440 in the light source region. The light source electrode 450 may be the P electrode, and the electrons in the electrode may be moved to the spacer layer 430 and the MQW active layer 420 through the second cladding layer 440.

The first insulating film 460 may be disposed between the light source electrode 450 and the heater 330. The first insulating film 460 may insulate the light source electrode 450 and the heater 330 from each other.

The heater 330 may be disposed on top of the first insulating film 460.

FIG. 6 is a view showing a cross-section taken along “reference C” in FIG. 3.

Referring to FIG. 6, based on “reference C”, the optical element 300 having a reverse mesa ridge structure may include the substrate 400, the first cladding layer 410, the MQW active layer 420, the spacer layer 430, the second cladding layer 440, the light source electrode 450, the first insulating film 460, the second insulating film 480, and the heater 330.

The first cladding layer 410 may be disposed on top of the substrate 400.

The MQW active layer 420 may be disposed on top of the first cladding layer 410.

The spacer layer 430 may be disposed on top of the MQW active layer 420.

The second cladding layer 440 may be disposed on top of one side of the spacer layer 430.

The second cladding layer 440 may have the lower width smaller than the upper width. For example, the second cladding layer 440 may have the reverse mesa structure.

The second BCB layer 480 may be disposed on top of the other side of the spacer layer 430, and spaced apart from the second cladding layer 440 to have a space 486 therebetween.

The light source electrode 450 may connect the top of the second cladding layer 440 to the top of the second BCB layer 480.

The first insulating film 460 may be disposed on top of one side of the light source electrode 450.

The heater 330 may be disposed on top of the first insulating film 460.

As described above, the space may be formed between the first BCB layer 470 and the second cladding layer 440, and the space may be formed between the second BCB layer 480 and the second cladding layer 440, thereby solving issues of semiconductor reliability reduction caused by a change in stress due to repeated temperature changes and a failure of heat generated from the heater to be concentrated in an active region when the spaces are filled.

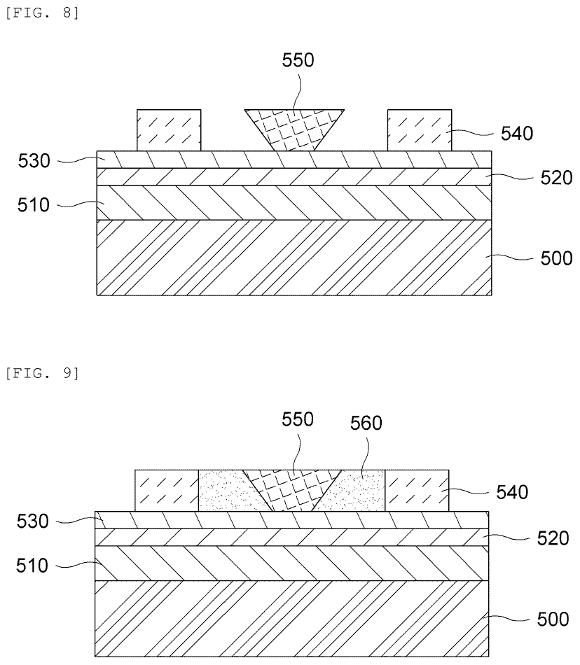

FIGS. 7 to 12 are views for explaining a manufacturing method of an optical element having a reverse mesa ridge structure according to an embodiment of the present disclosure.

Referring to FIG. 7, a first cladding layer 510 may be disposed on a substrate 500.

An MQW active layer 520 may be disposed on top of the first cladding layer 510.

A spacer layer 530 may be disposed on top of the MQW active layer 520.

A second cladding layer 550 may be disposed on top of one side of the spacer layer 530.

The second cladding layer 550 may have a lower width smaller than an upper width.

A BCB layer 540 may be applied to and disposed on each of two sides of the second cladding layer 550 disposed on top of the spacer layer 530.

Referring to FIG. 8, the second BCB layer 540 may be disposed on a left side of the second cladding layer 550 to be spaced apart from the second cladding layer 550 and the first BCB layer 540 may be disposed on a right side of the second cladding layer 550 to be spaced apart from the second cladding layer 550 by removing portions of the BCB layers 540 disposed on the two sides of the second cladding layer 550. In other words, the two BCB layers 540 may be disposed on the two sides of the second cladding layer 550 to be spaced apart from each other.

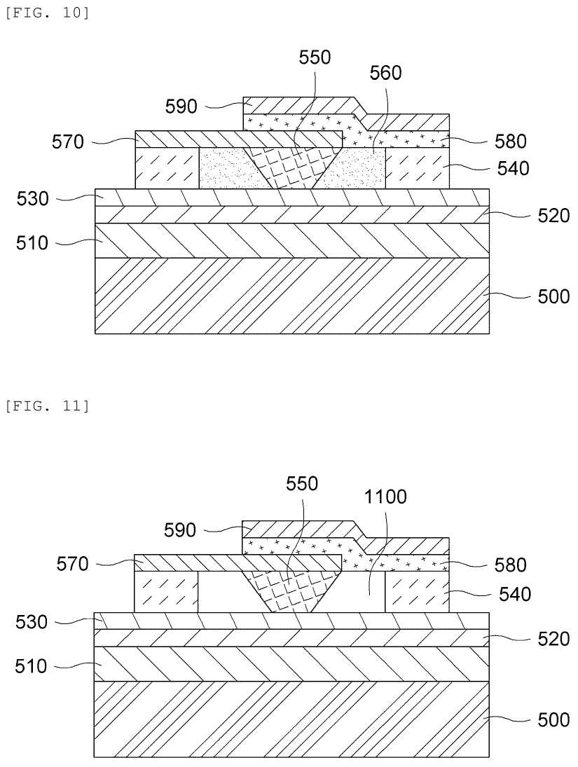

Referring to FIG. 9, a photoresist (PR) 560 may be applied to the portion where the BCB layer 540 in FIG. 8 is removed.

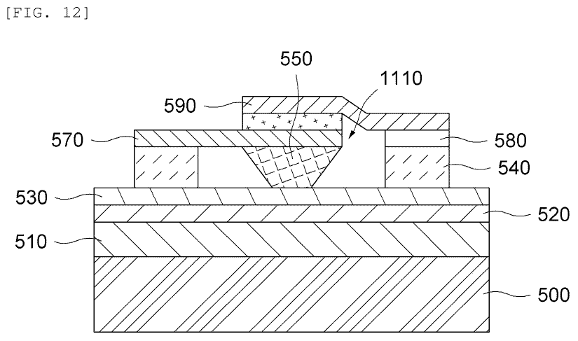

Referring to FIG. 10, a light source electrode 570 may be formed to connect the top of the second cladding layer 550 to the top of the second BCB layer (i.e., left side in FIG. 10).

Next, an insulating film 580 may be formed to connect the top of the light source electrode 570 to the top of the first BCB layer (i.e., right side in FIG. 10).

A heater 590 may be disposed on top of the insulating film 580.

Referring to FIG. 11, after the ridge structure may be completely manufactured according to FIG. 10, the photoresist (PR) may be removed to provide an air bridge structure 1100. In other words, spaces may be formed between the second cladding layer 550 and the first BCB layer 540, and between the second cladding layer 550 and the second BCB layer 540.

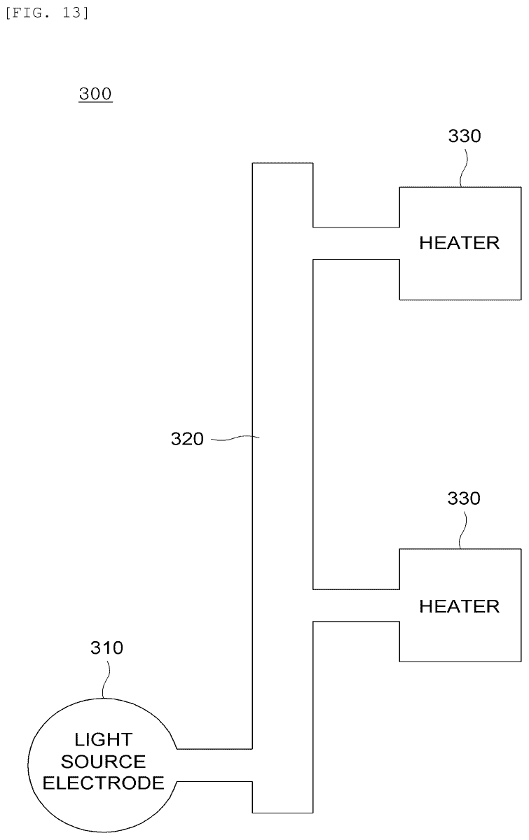

Referring to FIG. 12, an insulating film 1110 disposed in a portion of the insulating film 580 that corresponds to the air bridge structure may be removed.

The manufacturing order and process in this embodiment are provided for descriptive purposes, and may be modified in various ways, such as selectively executing some manufacturing processes or partially changing the manufacturing order.

Although the BCB and the PR are mentioned in the present disclosure, these materials may be replaced with other materials having similar properties.

In addition, the present disclosure does not necessarily have to follow this manufacturing process order, and use various manufacturing methods to provide the air bridge structure.

FIG. 13 is a view for explaining an optical element having a reverse mesa ridge structure according to another embodiment of the present disclosure.

The optical element 300 having a reverse mesa ridge structure may include the light source electrode 310, the wave guide 320, and the heater 330.

The two heaters 330 may be disposed on one side of the wave guide 320 to be spaced apart from each other.

The light source electrode 310 may be disposed on the other side of the wave guide 320, opposite to one side of the wave guide 320 where the two heaters 330 are disposed, to be outside the two heaters 330 disposed on one side of the wave guide 320 in a length direction of the wave guide 320 (“above/below the two heaters 330 as shown in FIG. 13”).

Referring to FIGS. 4, 5, and 6, the light source electrode 450 and the heater 330 may be formed as the different layers disposed on top of the semiconductor chip, and a position of the heater 330 and a position of the light source electrode 450 may thus be freely selected.

However, the heater may be disposed on top of the light electrode layer. Accordingly, if a pad of the light source electrode 310 is disposed between the two heaters 330 as shown in FIG. 3, a height difference may occur on a surface of a portion of the light source electrode 310 where its pads are connected to each other. This height difference may reduce the stability of the heater deposited on the light source electrode. Therefore, as shown in FIG. 13, the light source electrode 310 may preferably be disposed below the heater 330 (see FIG. 13). In other words, the light source electrode 310 may be disposed below the wave guide 320. However, the position where the light source electrode 310 is connected to the wave guide 320 is only an example, and may be changed in various ways.

As set forth above, in the optical element having a reverse mesa ridge structure according to the present disclosure, heat generated from the heater may be concentrated in the multi-quantum structure (MQS) active region in the semiconductor to thus increase energy efficiency, and the BCB may minimize its contact with the ridge when manufacturing the reverse mesa ridge structure to thus effectively eliminate the stress applied to the semiconductor, thereby enhancing the semiconductor reliability.

All or some of the respective embodiments may be selectively combined with each other so that the above-mentioned embodiments may be variously modified.

In addition, it should be noted that the embodiments are provided in order to describe the present disclosure rather than limiting the present disclosure. In addition, an expert in a technical field of the present disclosure will understand that various embodiments are possible within the spirit and scope of the present disclosure.

What is claimed is:

1. An optical element having a reverse mesa ridge structure, the element comprising:
a substrate;
a second cladding layer disposed near a center of the top of the substrate;
a first benzocyclobutene (BCB) layer disposed on a right side of the second cladding layer and spaced apart from the second cladding layer to have a space therebetween;
a second BCB layer disposed on a left side of the second cladding layer and spaced apart from the second cladding layer to have a space therebetween;
a light source electrode connecting the top of the second cladding layer to the top of the second BCB layer;
an insulating film connecting the top of the light source electrode to the top of the first BCB layer; and
a heater disposed on top of the insulating film connecting the top of the light source electrode to the top of the first BCB layer.

2. The element of claim 1, further comprising a first cladding layer disposed on top of the substrate.

3. The element of claim 2, further comprising a multi-quantum well (MQW) active layer disposed on top of the first cladding layer.

4. The element of claim 3, further comprising a spacer layer disposed on top of the MQW active layer,
wherein the second cladding layer is disposed near a center of the top of the spacer layer.

5. The element of claim 1, wherein the second cladding layer has a lower width smaller than an upper width.

6. The element of claim 1, wherein the two heaters are disposed on one side of a wave guide to be spaced apart from each other, and
the light source electrode is disposed on the other side of the wave guide, opposite to the one side of the wave guide where the two heaters are disposed.

7. The element of claim 1, wherein the two heaters are disposed on two ends of one side of the wave guide to be spaced apart from each other, and
the light source electrode is disposed between the two heaters and on the other side of the wave guide, opposite to the one side of the wave guide where the two heaters are disposed.

8. A manufacturing method of an optical element having a reverse mesa ridge structure, the method comprising:
disposing a second cladding layer near a center of the top of a substrate;
disposing a benzocyclobutene (BCB) layer on each of two sides of the second cladding layer disposed on top of the substrate;
disposing a first BCB layer on a right side of the second cladding layer to be spaced apart from the second cladding layer and a second BCB layer on a left side of the second cladding layer to be spaced apart from the second cladding layer by removing portions of the BCB layers disposed on the two sides of the second cladding layer;
applying a photoresist (PR) to the removed BCB layer and filling the removed BCB layer with the photoresist (PR);
disposing a light source electrode to connect the top of the second cladding layer to the top of the second BCB layer;
disposing an insulating film to connect the top of the light source electrode to the top of the first BCB layer;
disposing a heater on top of the insulating film connecting the top of the light source electrode to the top of the first BCB layer; and
providing an air bridge structure by removing the photoresist (PR) disposed between the second cladding layer and the first BCB layer and between the second cladding layer and the second BCB layer.

9. The method of claim 8, further comprising disposing a first cladding layer on top of the substrate.

10. The method of claim 9, further comprising disposing a multi-quantum well (MQW) active layer on top of the first cladding layer.

11. The method of claim 10, further comprising disposing a spacer layer on top of the MQW active layer,
wherein the second cladding layer is disposed near a center of the top of the spacer layer.

12. The method of claim 8, wherein the second cladding layer has a lower width smaller than an upper width.
